(19) United States
(12) Patent Application Publication
(10) Pub. No.: US 2026/0171364 A1
(43) Pub. Date: Jun. 18, 2026

(54) PASSIVATING MICROWAVE DIELECTRICS FOR SEMICONDUCTOR MANUFACTURING

(71) Applicant: Applied Materials, Inc., Santa Clara, CA (US)

(72) Inventors: KELVIN CHAN, San Ramon, CA (US); WEI LEI, Campbell, CA (US); ESTEBAN BAEZA RUZ, Sunnyvale, CA (US); SHIYU YUE, Sunnyvale, CA (US); ASHUTOSH AGARWAL, San Jose, CA (US); SANJEEV BALUJA, Campbell, CA (US); KENJI TAKESHITA, Santa Clara, CA (US)

(21) Appl. No.: 18/983,074

(22) Filed: Dec. 16, 2024

(51) Int. Cl. H01J 37/32

(52) U.S. Cl. CPC H01J 37/32247; H01J 37/32302; H01J 2237/332

(57) ABSTRACT

Embodiments described herein relate to an apparatus that includes a dielectric plate with a first surface and a second surface opposite from the first surface. In an embodiment, a dielectric resonators on the second surface of the dielectric plate. In an embodiment, a coating is on the first surface of the dielectric plate, where the coating includes yttrium and/or zirconium.

### BACKGROUND

### 1) Field

Embodiments relate to the field of semiconductor manufacturing and, in particular, to passivating layers for dielectric surfaces within microwave plasma chambers.

### 2) Description of Related Art

Contamination is a significant risk during the manufacture of semiconductor devices. In the case of microwave plasma chambers, high-density radicals and ions are present, and the radicals and ions may damage dielectric surfaces within the chamber. In the case of aluminum oxide or silicon oxide dielectrics, aluminum or silicon may leach out from the exposed dielectric materials and contaminate the chamber and/or a substrate within the chamber.

The aluminum and/or silicon contamination may be mitigated by forming a coating over the dielectric. In instances where aluminum contamination is an issue, a silicon oxide coating or a silicon nitride coating may be provided over the aluminum oxide surfaces. These coatings may need to be replaced periodically since they will degrade over time. This leads to chamber down time since passivation processes need to be run periodically. When silicon contamination is a concern, there are currently not any coatings that provide good mitigation of the silicon contamination. As such, regular cleanings may be necessary to minimize silicon contamination.

### SUMMARY

Embodiments described herein relate to an apparatus that includes a dielectric plate with a first surface and a second surface opposite from the first surface. In an embodiment, a dielectric resonator on the second surface of the dielectric plate. Though, in other embodiments, a single dielectric resonator may also be on the dielectric plate. In an embodiment, a coating is on the first surface of the dielectric plate, where the coating includes yttrium and/or zirconium.

Embodiments described herein relate to an apparatus that includes a dielectric plate with a first surface and a second surface opposite from the first surface, where a channel is embedded within the dielectric plate, and where the channel exits the dielectric plate at the first surface. In an embodiment, the apparatus further includes a dielectric resonators on the second surface of the dielectric plate, and a coating on the first surface of the dielectric plate and on surfaces of the channel, where the coating includes yttrium and/or zirconium. Embodiments described herein relate to an apparatus that includes a chamber, and dielectric plate to seal an opening of the chamber, where a surface of the dielectric plate within the chamber is covered by a coating including yttrium and/or zirconium. In an embodiment, a plurality of dielectric resonators are on the dielectric plate outside of the chamber. In an embodiment, the apparatus further includes a plurality of solid state power sources, where each of the plurality of solid state power sources is electrically coupled to a corresponding one of the plurality of dielectric resonators, and where each of the plurality of solid state power sources is configured to emit electromagnetic radiation with a frequency of at least 1.0 GHz.

### BRIEF DESCRIPTION OF THE DRAWINGS

FIG. 1A is a perspective view illustration of a modular high-frequency emission source for a microwave plasma chamber, in accordance with an embodiment.

FIG. 1B is a cross-sectional illustration of the modular high-frequency emission source for the microwave plasma chamber, in accordance with an embodiment.

FIG. 2A is a cross-sectional illustration of a modular high-frequency emission source where a dielectric plate comprises a passivating coating, in accordance with an embodiment.

FIG. 2B is a cross-sectional illustration of a modular high-frequency emission source where the dielectric plate and the dielectric resonators comprise a passivating coating, in accordance with an embodiment.

FIG. 3A is a cross-sectional illustration of a dielectric surface with a passivating coating, in accordance with an embodiment.

FIG. 3B is a cross-sectional illustration of a dielectric surface with a passivating coating that comprises a first layer and a second layer, in accordance with an embodiment.

FIG. 4 is a cross-sectional illustration of a microwave plasma tool that includes a modular high-frequency emission module that comprises a passivating coating on surfaces exposed to an interior of the chamber, in accordance with an embodiment.

FIG. 5 is a schematic illustration of a high-frequency solid state power source for use in a microwave plasma chamber, in accordance with an embodiment.

FIG. 6 illustrates a block diagram of an exemplary computer system that may be used in conjunction with a high frequency plasma tool, in accordance with an embodiment.

### DETAILED DESCRIPTION

Embodiments described herein include passivating layers for dielectric surfaces within microwave plasma chambers. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, contamination is a significant risk during the manufacture of semiconductor devices. In the case of microwave-plasma chambers, high-density radicals and ions are present, and the radicals and ions may damage dielectric surfaces within the chamber. In the case of aluminum oxide or silicon oxide dielectrics, aluminum or silicon may leach out from the dielectric and contaminate the chamber and/or a substrate within the chamber.

The aluminum and/or silicon contamination may be mitigated by forming a coating over the dielectric. However, the coatings need to be regularly reapplied due to the interactions with the species within the plasma. As such, regular cleanings may be necessary to minimize contamination. Some proposals have included the use of yttrium based passivating layers due to the low reactivity of yttrium to the plasma species. However, in existing plasma chambers, the plasmas are operated at relatively low frequencies (e.g., 200 MHz or lower). This results in high energy ions that result in a sputtering effect that damages and erodes the passivating coating.

However, embodiments disclosed herein may include the use of passivating coatings that comprise one or both of yttrium or zirconium (e.g., yttrium oxide (YO), zirconium oxide (ZO), or yttrium zirconium oxide (YZO)). In contrast to their use in low frequency plasma chambers, such passivating coatings have good resistance to erosion when used with high-frequency plasma sources. For example, with plasma frequencies of approximately 1.0 GHz or higher, the ions of the plasma have a relatively low energy. As such, there is minimal sputtering that degrades the passivating coatings.

Further, the yttrium and zirconium have good chemical resistance with respect to typical plasma processing chemistry, such as hydrogen, fluorine, chlorine, or the like. Particularly, the hydrides, nitrides, fluorides, and chlorides of yttrium and zirconium are non-volatile. As such, when those species are formed, the species do not release from the passivating coating, and there is not a large risk of redeposition on the substrate and/or along interior surfaces of the chamber.

In some embodiments, the high-frequency plasma chambers may be fabricated with a modular approach. In a modular approach, a plurality of dielectric resonators are coupled to a dielectric plate to form a modular high-frequency emission source. The high-frequency emission source may function as a lid to seal an opening of the chamber. The dielectric plate may have a surface that is exposed to an interior of the chamber. As such, the interior surface of the high-frequency emission source may be covered by a passivation layer that comprises yttrium and/or zirconium to prevent contamination.

In some instances, the high-frequency emission source may also include internal channels that are used to supply gas into the chamber. Since the internal channels are fluidly coupled to the chamber interior, the surfaces of the channels are also exposed to potentially damaging chemistries. As such, the surfaces of the channels may also be coated with a passivating coating that comprises yttrium and/or zirconium.

Embodiments may also include coating interior dielectric surfaces of the chamber with such a passivating coating. For example, interior walls of the chamber, chamber liners, process kits, and/or the like may be coated with a passivating coating that comprises yttrium and/or zirconium.

In an embodiment, the passivating coating may be a single monolithic layer. In other embodiments, the passivating coating may comprise a plurality of stacked layers. For example, a first layer that is directly on the dielectric surface that needs protection may be an adhesion promoting layer, and the second layer may include a the yttrium and/or zirconium composition. Since the first layer is not exposed to the plasma, the first layer may comprise a material that may have a composition that does not include the yttrium and/or zirconium For example, the first layer may comprise aluminum oxide.

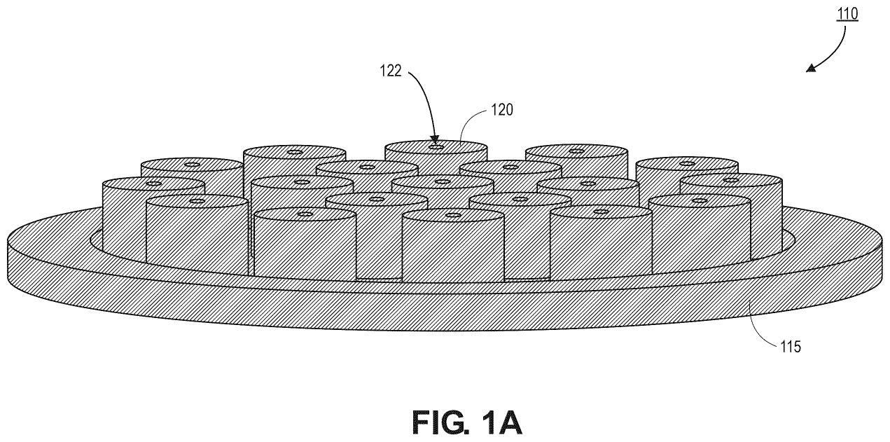

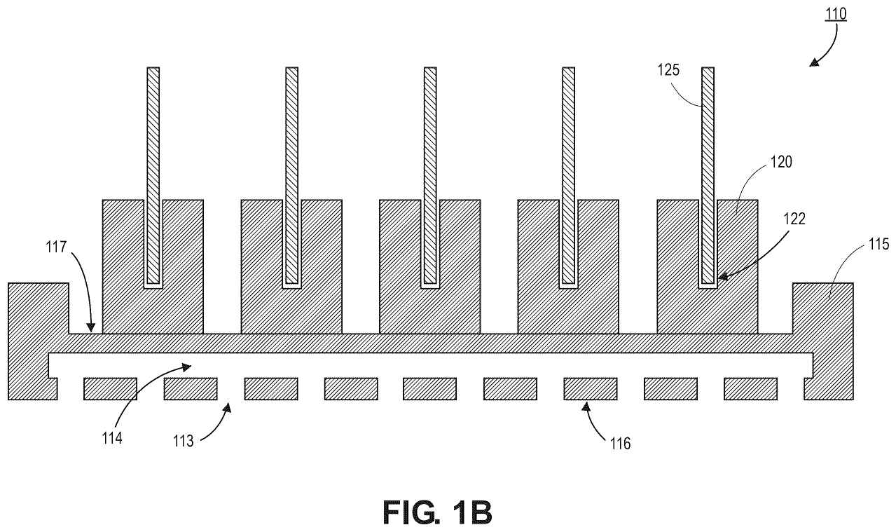

Referring now to FIG. 1A, a perspective view illustration of a high-frequency emission source 110 that can be used in a modular microwave plasma chamber is shown, in accordance with an embodiment. In an embodiment, the high-frequency emission source 110 may comprise a dielectric plate 115 and a plurality of dielectric resonators 120 distributed across a surface of the dielectric plate 115. Though, in other embodiments, a single dielectric resonator 120 may also be provided on the dielectric plate 115. In an embodiment, the dielectric plate 115 and the dielectric resonators 120 may be discrete components. Though, in other embodiments, the dielectric plate 115 and the dielectric resonators 120 may comprise a monolithic structure.

In an embodiment, the dielectric resonators 120 may be sized to produce a dielectric resonant cavity for a particular frequency of electromagnetic energy. For example, a monopole antenna (not shown) may be inserted into holes 122 that are formed into the dielectric resonators 120, and the monopole antenna may be electrically coupled to a high-frequency power source. The resonating electromagnetic energy may then be distributed through the dielectric plate 115 and into the chamber (not shown) below the dielectric plate 115.

In an embodiment, the dielectric resonators 120 and the dielectric plate 115 may comprise any suitable dielectric material. For example, the dielectric material may be chosen based on a desired dielectric constant that allows for the generation of a dielectric resonant cavity for a desired frequency of electromagnetic radiation. In some embodiments, the dielectric resonators 120 and/or the dielectric plate 115 may comprise alumina, sapphire, quartz, or the like.

Referring now to FIG. 1B, a cross-sectional illustration of the high-frequency emission source 110 is shown, in accordance with an embodiment. As shown, the dielectric plate 115 may comprise a top surface 117 and a bottom surface 116. The dielectric resonators 120 may be provided on the top surface 117. While shown as discrete components, the dielectric resonators 120 may also be part of a monolithic structure with the dielectric plate 115.

In an embodiment, the dielectric resonators 120 may comprise a dielectric body with a hole 122 into which an antenna 125 is inserted. For example, the antenna 125 may comprise a conductive line (e.g., a monopole) that extends into the dielectric resonator 120. In some embodiments, the antenna 125 is in direct contact with the dielectric resonator 120. In other embodiments, the hole 122 is larger than the antenna 125, and the antenna 125 is spaced away from surfaces of the dielectric resonator 120. In some instances, the antenna 125 may be referred to as a rod or a metallic rod. The antenna 125 may comprise any suitable electrically conductive material. For example, the antenna 125 may comprise copper or an alloy of copper and beryllium.

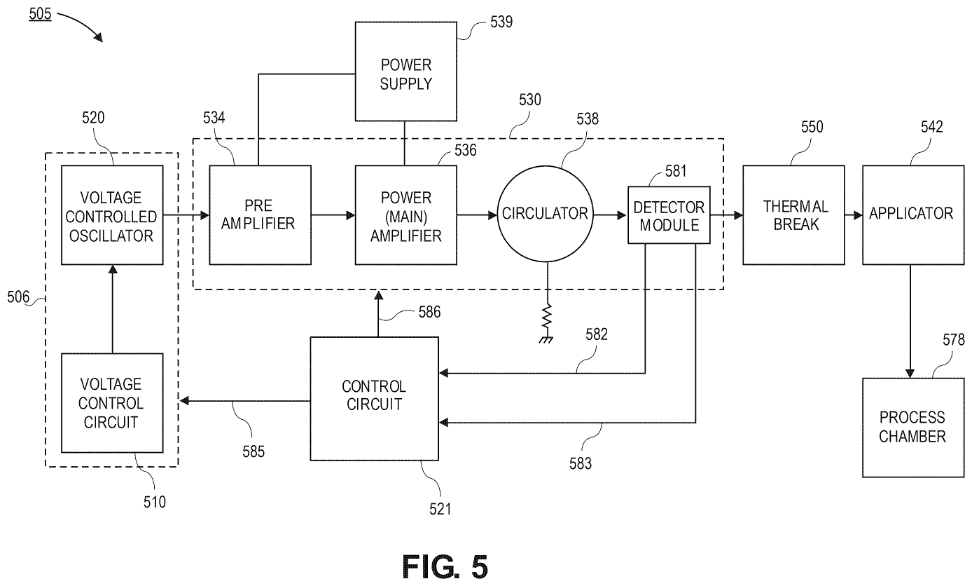

In an embodiment, an end of each antenna 125 may be electrically coupled to different high-frequency solid state power sources (not shown). As used herein, “high frequency” electromagnetic radiation may include radio frequency radiation, very-high frequency radiation, ultra-high frequency radiation, and microwave radiation. “High frequency” may refer to frequencies between 0.1 MHz and 300 GHz. In an embodiment, the high-frequency solid state power sources may comprise a plurality of sub-components, such as an oscillator, amplifiers, and other circuitry blocks. A more detailed description of the high-frequency solid state power sources is provided below with respect to FIG. 5.

In an embodiment, one or more channels 114 may be embedded within the dielectric plate 115. For example, the channels 114 may be used to distribute gas from a gas source (not shown) through the dielectric plate 115 and into a chamber (not shown). For example, outlets 113 from the channels 114 may fluidically couple the channels 114 to an interior of the chamber to which the high-frequency emission source 110 is coupled.

In an embodiment, the high-frequency emission source 110 is coupled to a plasma chamber. During operation of the chamber (e.g., to generate a plasma), surfaces of the high-frequency emission source 110 are exposed to the plasma. When the dielectric plate 115 comprises silicon (e.g., quartz) or aluminum (e.g., alumina), the dielectric plate 115 may be a source of contamination for the chamber and/or substrates that are processed within the chamber. Accordingly, embodiments disclosed herein may include high-frequency emission sources that have a passivating coating provided over surfaces that are exposed to the plasma environment.

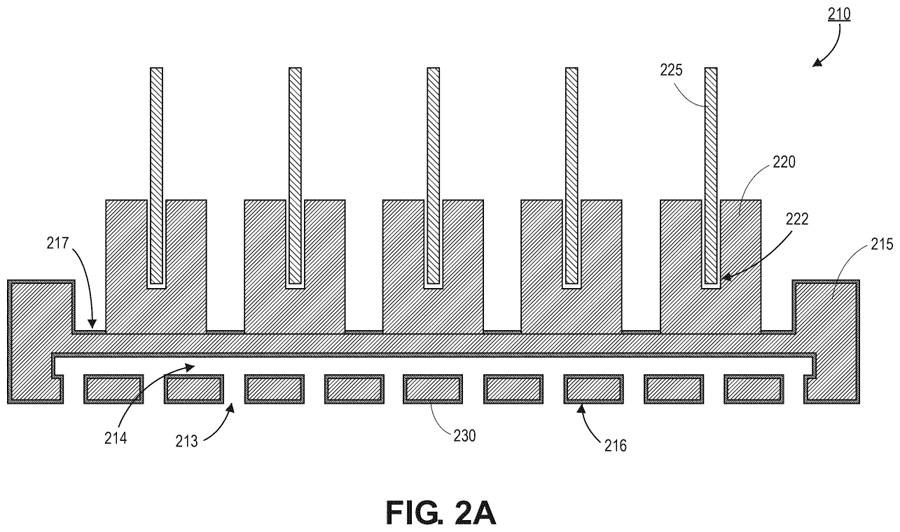

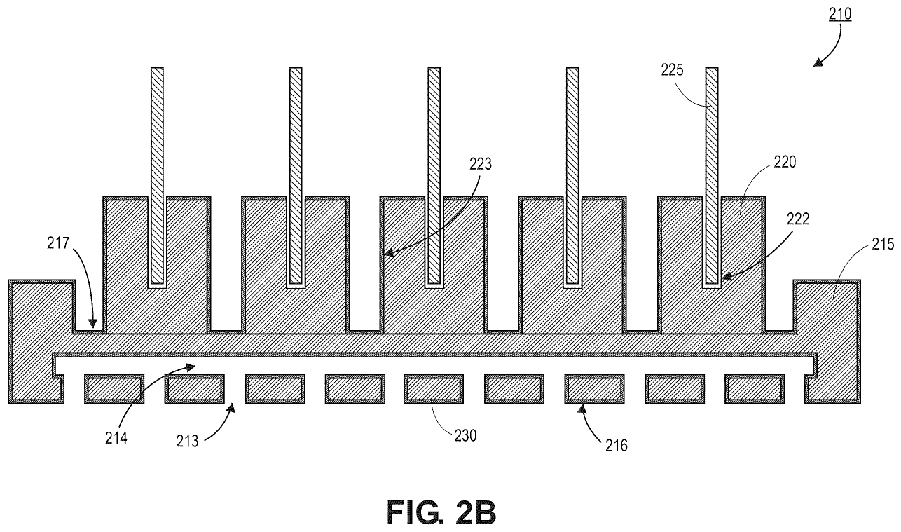

Referring now to FIGS. 2A and 2B, cross-sectional illustrations depicting different high-frequency emission sources 210 that have a passivation coating 230 are shown, in accordance with various embodiments. In an embodiment, the high-frequency emission sources 210 in FIGS. 2A and 2B may be substantially similar to the high-frequency emission source 110 in FIGS. 1A and 1B, with the addition of the coating 230 over different surfaces.

In an embodiment, the coating 230 may be a dielectric material that has a chemistry that has constituents that are not rendered volatile when exposed to a plasma environment. For example, in the case of a hydrogen-based plasma, a fluorine-based plasma, a chlorine-based plasma, or the like, the coating 230 may comprise one or both of yttrium or zirconium. As noted above, the hydrides, nitrides, fluorides, and chlorides of yttrium and zirconium are non-volatile. As such, they do not leach out of the coating 230 and redeposit on surfaces of the chamber and/or on substrates processed in the chamber. Further, when the high-frequency plasma produces ions with low energy that do not erode the coating 230. In some embodiments, the coating 230 may comprise one or more of yttrium oxide, zirconium oxide, or yttrium zirconium oxide.

In an embodiment, the coating 230 may be applied over surfaces of the high-frequency emission source 210 using any suitable process. For example, a conformal deposition process (e.g., atomic layer deposition (ALD)) may be used to deposit the coating 230 onto surface of the high-frequency emission source 210. A conformal deposition process allows for the coating 230 to be provided along internal surfaces, such as gas distribution channels and/or the like.

Referring now to FIG. 2A, a cross-sectional illustration of a high-frequency emission source 210 is shown, in accordance with an embodiment. As shown, the high-frequency emission source 210 may comprise a coating 230 that is provided over surfaces of the dielectric plate 215. Particularly, the coating 230 may be applied over surfaces that are exposed to the plasma environment, such as a bottom surface 216 of the dielectric plate 215 and internal surfaces along the channel 214 and outlets 213. As such, portions of the dielectric plate 215 that are exposed to the plasma will be protected in order to limit contamination from silicon, aluminum, and/or the like.

While the coating 230 is provided over surfaces of the dielectric plate 215 that will be exposed to the plasma, embodiments may also include providing the coating 230 over substantially all of the dielectric plate 215. For example, the coating 230 may also be formed over the top surface 217 of the dielectric plate in some embodiments. Providing the coating 230 over all surfaces may make the coating deposition simpler since selected portions of the dielectric plate 215 do not need to be masked during the deposition process.

Referring now to FIG. 2B, a cross-sectional illustration of a high-frequency emission source 210 is shown, in accordance with an additional embodiment. As shown, the high-frequency emission source 210 in FIG. 2B may be substantially similar to the high-frequency emission source 210 in FIG. 2A, with the exception of the coverage of the passivation coating 230. In FIG. 2B, the passivation coating 230 is also provided over surfaces 223 of the dielectric resonators 220. In some embodiments, the hole 222 may be uncoated (as shown in FIG. 2B). Though, in other embodiments, the surfaces of the hole 222 may also be covered by the coating 230. That is, the antenna 225 may be separated from the dielectric resonator 220 by the coating 230 in some embodiments.

In some embodiments, coating the dielectric resonators 220 may be a manufacturing choice, since the dielectric resonators 220 may not typically be exposed to the plasma environment. For example, in the case of a monolithic high-frequency emission source 210, the coating 230 may be applied to the entire high-frequency emission source 210 with a single deposition process. As such, the deposition of the coating 230 is simplified since there may not be a reason to mask portions of the high-frequency emission source 210 in order to selectively apply the coating 230.

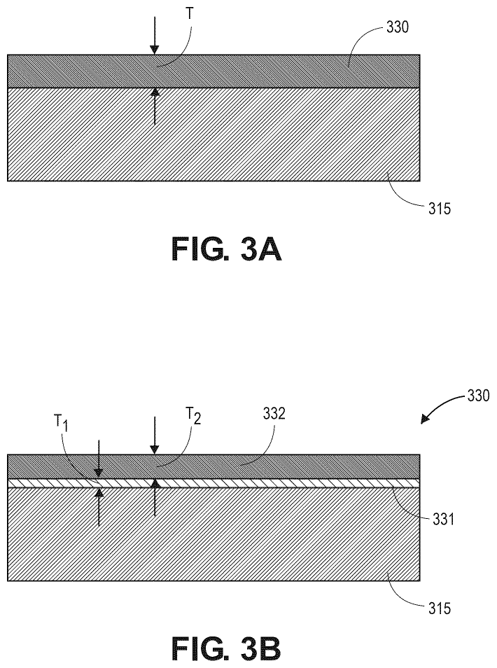

In an embodiment, the passivation coating may have any suitable composition and/or structure. For example, FIGS. 3A and 3B are zoomed in cross-sectional illustrations of a portion of a dielectric plate 315 and the coating 330 for a high-frequency emission module, in accordance with various embodiments. In FIG. 3A, the coating 330 may comprise a single layer. The single layer may have a substantially uniform composition through a thickness T of the coating 330. For example, the coating 330 may comprise a substantially uniform concentration of yttrium and/or zirconium through a thickness direction of the coating 330.

In an embodiment, the thickness T of the coating 330 may be any suitable thickness. For example, the thickness T may be up to approximately 25 nm, up to approximately 100 nm, up to approximately 500 nm, or up to approximately 1,000 nm. Though thicker coatings 330 may also be used in some embodiments. In an embodiment, the thickness T of the coating 330 may be substantially uniform across the dielectric plate 315 (including within internal gas delivery channels). For example, the use of a conformal deposition process may result in a highly uniform thickness T of the coating 330 across the dielectric plate 315.

Referring now to FIG. 3B, a cross-sectional illustration of a portion of a dielectric plate 315 with a coating 330 is shown, in accordance with an additional embodiment. In the embodiment shown in FIG. 3B, the coating 330 comprises a plurality of layers. For example, a first layer 331 may be directly in contact with the dielectric plate 315, and a second layer 332 may be provided on the first layer 331. In some embodiments, one or more additional layers may be provided over the second layer 332.

In an embodiment, the first layer 331 may be used as an adhesion layer and the second layer 332 may comprise one or both of yttrium or zirconium. In some instances, the adhesion properties of the first layer 331 may be better than the adhesion properties of the second layer 332. Further, the first layer 331 may be tuned to have a high adhesion since the first layer 331 is covered by the second layer 332 and is not exposed to the plasma environment. As such, the first layer 331 may include a constituents that may otherwise be contamination risks. For example, the first layer 331 may comprise aluminum (e.g., aluminum oxide) and/or silicon (e.g., silicon oxide).

In an embodiment, the first layer 331 may have a first thickness T₁ and the second layer 332 may have a second thickness T₂. The first thickness T₁ may be different than the second thickness T₂ in some embodiments. For example, the first thickness T₁ may be smaller than the second thickness T₂. In an embodiment, the first thickness T₁ may be less than approximately 100 nm and the second thickness T₂ may be greater than approximately 100 nm, greater than approximately 200 nm, or greater than approximately 500 nm.

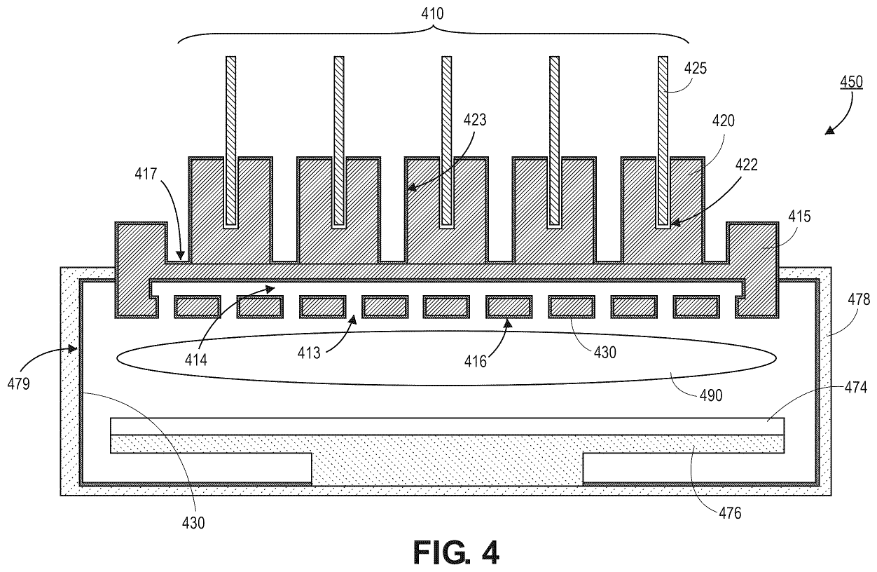

Referring now to FIG. 4, a cross-sectional schematic illustration of a processing system 450 with a modular high-frequency emission source 410 is shown, in accordance with an embodiment. In an embodiment, the modular high-frequency emission source 410 may comprise a plurality of high-frequency emission channels. For example, the high-frequency emission channels may each comprise a solid state power source (not shown) that is electrically coupled to a dielectric resonator 420 by an antenna 425 that is inserted into a hole 422 of the dielectric resonator 420. The dielectric resonators 420 may be provided on a top surface 417 of a dielectric plate 415. In the illustrated embodiment, the dielectric resonators 420 and the dielectric plate 415 are discrete components. Though, in other embodiments the dielectric resonators 420 and the dielectric plate 415 may be a monolithic structure.

In an embodiment, the modular high-frequency emission source 410 may inject high frequency electromagnetic radiation into a chamber 478 through the dielectric plate 415 of the high-frequency emission source 410. The high-frequency electromagnetic radiation may induce a plasma 490 in the chamber 478. The plasma 490 may be used to process a substrate 474 that is positioned on a support 476 (e.g., an electrostatic chuck (ESC) or the like).

In an embodiment, the plasma 490 within the chamber 478 may lead to erosion of dielectric surfaces within the chamber 478. Accordingly, the dielectric surfaces of the high-frequency emission source 410 and/or dielectric surfaces of the interior of the chamber 478 may be covered by a passivation coating 430. The passivation coating 430 may comprise one or both of yttrium or zirconium. For example, the passivation coating 430 may comprise yttrium oxide, zirconium oxide, and/or yttrium zirconium oxide. In an embodiment, the passivation coating 430 may be similar to any of the coatings described in greater detail herein. For example, the passivation coating 430 may have a single layer or the passivation coating 430 may comprise a plurality of layers (e.g., an adhesion layer and a layer comprising yttrium and/or zirconium).

In an embodiment, the passivation coating 430 may be provided along a bottom surface 416 of the dielectric plate 415. Additionally, the passivation coating 430 may cover surfaces of an interior gas channel 414 and gas outlets 413 of the dielectric plate 415. In the illustrated embodiment, the passivation coating 430 is also provided along an interior surface 479 of the chamber 478. The passivation coating 430 may also be provided over dielectric chamber liners, process kits, and/or the like. Accordingly, the interior surfaces of the chamber 478 are protected from the plasma 490, and contamination (e.g., from aluminum, silicon, and/or the like) is minimized. Similar to FIG. 2B, the passivation coating 430 may also be provided over the top surface 417 of the dielectric plate 415 and over surfaces 423 of the dielectric resonators 420. Though, the top surface 417 and/or the dielectric resonators 420 may be uncoated in some embodiments as well.

Referring now to FIG. 5, a schematic of a solid state power source 505 is shown, in accordance with an embodiment. In an embodiment, the solid state power source 505 comprises an oscillator module 506. The oscillator module 506 may include a voltage control circuit 510 for providing an input voltage to a voltage controlled oscillator 520 in order to produce high frequency electromagnetic radiation at a desired frequency. Embodiments may include an input voltage between approximately 1V and 10V DC. The voltage controlled oscillator 520 is an electronic oscillator whose oscillation frequency is controlled by the input voltage. According to an embodiment, the input voltage from the voltage control circuit 510 results in the voltage controlled oscillator 520 oscillating at a desired frequency. In an embodiment, the high frequency electromagnetic radiation may have a frequency between approximately 0.1 MHz and 30 MHz. In an embodiment, the high frequency electromagnetic radiation may have a frequency between approximately 30 MHz and 300 MHz. In an embodiment, the high frequency electromagnetic radiation may have a frequency between approximately 300 MHz and 1 GHz. In an embodiment, the high frequency electromagnetic radiation may have a frequency between approximately 1 GHz and 300 GHz.

According to an embodiment, the electromagnetic radiation is transmitted from the voltage controlled oscillator 520 to an amplification module 530. The amplification module 530 may include a driver/pre-amplifier 534, and a main power amplifier 536 that are each coupled to a power supply 539. According to an embodiment, the amplification module 530 may operate in a pulse mode. For example, the amplification module 530 may have a duty cycle between 1% and 99%. In a more particular embodiment, the amplification module 530 may have a duty cycle between approximately 15% and 50%.

In an embodiment, the electromagnetic radiation may be transmitted to the thermal break 550 and the applicator 542 after being processed by the amplification module 530. However, part of the power transmitted to the thermal break 550 may be reflected back due to the mismatch in the output impedance. Accordingly, some embodiments include a detector module 581 that allows for the level of forward power 583 and reflected power 582 to be sensed and fed back to the control circuit module 521. It is to be appreciated that the detector module 581 may be located at one or more different locations in the system. In an embodiment, the control circuit module 521 interprets the forward power 583 and the reflected power 582, and determines the level for the control signal 585 that is communicatively coupled to the oscillator module 506 and the level for the control signal 586 that is communicatively coupled to the amplifier module 530. In an embodiment, control signal 585 adjusts the oscillator module 506 to optimize the high frequency radiation coupled to the amplification module 530. In an embodiment, control signal 586 adjusts the amplifier module 530 to optimize the output power coupled to the applicator 542 through the thermal break 550. In an embodiment, the feedback control of the oscillator module 506 and the amplification module 530, in addition to the tailoring of the impedance matching in the thermal break 550 may allow for the level of the reflected power to be less than approximately 5% of the forward power. In some embodiments, the feedback control of the oscillator module 506 and the amplification module 530 may allow for the level of the reflected power to be less than approximately 2% of the forward power.

Accordingly, embodiments allow for an increased percentage of the forward power to be coupled into the processing chamber 578, and increases the available power coupled to the plasma. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 520.

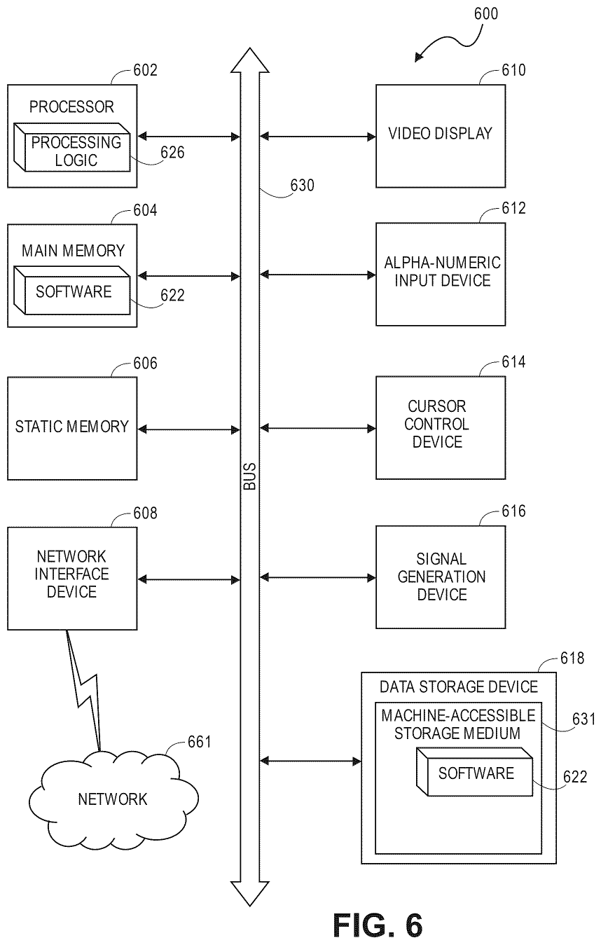

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a dielectric plate with a first surface and a second surface opposite from the first surface;
a dielectric resonator on the second surface of the dielectric plate; and
a coating on the first surface of the dielectric plate, wherein the coating comprises yttrium and/or zirconium.

2. The apparatus of claim 1, wherein the coating further comprises oxygen.

3. The apparatus of claim 1, wherein the dielectric plate comprises one or more of alumina, sapphire, or quartz.

4. The apparatus of claim 1, wherein the coating comprises a first layer in contact with the first surface of the dielectric plate and a second layer on the first layer, wherein the first layer and the second layer have different compositions.

5. The apparatus of claim 4, wherein the first layer comprises aluminum and oxygen, and wherein the second layer comprises the yttrium and/or zirconium.

6. The apparatus of claim 4, wherein the first layer has a first thickness and the second layer has a second thickness, wherein the second thickness is greater than the first thickness.

7. The apparatus of claim 1, further comprising:
a plurality of dielectric resonators on the second surface of the dielectric plate.

8. The apparatus of claim 7, wherein each of the plurality of dielectric resonators are coupled to different solid state power sources configured to resonate in response to electromagnetic radiation with a frequency of at least 1.0 GHz.

9. The apparatus of claim 8, wherein the dielectric plate seals an opening of a chamber.

10. The apparatus of claim 9, wherein an interior dielectric surface of the chamber is covered by the coating.

11. An apparatus, comprising:
a dielectric plate with a first surface and a second surface opposite from the first surface, wherein a channel is embedded within the dielectric plate, and wherein the channel exits the dielectric plate at the first surface;
a dielectric resonator on the second surface of the dielectric plate; and
a coating on the first surface of the dielectric plate and on surfaces of the channel, wherein the coating comprises yttrium and/or zirconium.

12. The apparatus of claim 11, wherein the coating comprises yttrium oxide or zirconium oxide.

13. The apparatus of claim 11, wherein the coating comprises yttrium zirconium oxide.

14. The apparatus of claim 11, wherein the coating comprises a first layer and a second layer over the first layer.

15. The apparatus of claim 14, wherein the first layer comprises aluminum oxide, and wherein the second layer comprises the yttrium and/or zirconium.

16. The apparatus of claim 14, wherein the first layer has a first thickness and the second layer has a second thickness that is greater than the first thickness.

17. The apparatus of claim 11, wherein the dielectric plate comprises one or more of alumina, sapphire, or quartz.

18. An apparatus, comprising:
a chamber;
dielectric plate to seal an opening of the chamber, wherein a surface of the dielectric plate within the chamber is covered by a coating comprising yttrium and/or zirconium;
a plurality of dielectric resonators on the dielectric plate outside of the chamber; and
a plurality of solid state power sources, wherein each of the plurality of solid state power sources is electrically coupled to a corresponding one of the plurality of dielectric resonators, and wherein each of the plurality of solid state power sources is configured to emit electromagnetic radiation with a frequency of at least 1.0 GHz.

19. The apparatus of claim 18, wherein a dielectric surface within the chamber is covered by the coating.

20. The apparatus of claim 18, wherein the coating comprises one or more of yttrium oxide, zirconium oxide, or yttrium zirconium oxide.
